(19) United States
(12) Patent Application Publication
(10) Pub. No.: US 2002/0177085 A1
(43) Pub. Date: Nov. 28, 2002

(54) Self-aligned photolithographic process for forming silicon-on-insulator devices

(76) Inventor: Benjamin Szu-Min Lin, Hsinchu (TW)

Correspondence Address: J.C. Patents, Inc., 4 VENTURE, SUITE 250, Irvine, CA, 92618, US

(21) Appl. No.: 09/864,056

(22) Filed: May 23, 2001

(51) Int. Cl. G03F 7/20

(52) U.S. Cl. 430/396; 430/311; 430/313

(57) ABSTRACT

A self-aligned photolithographic process for forming silicon-on-insulator devices. A substrate made from a transparent insulating material is provided. Conductive devices made from a non-transparent material, material layers made from transparent material and a photoresist layer are formed over the substrate. Transparent substrate areas having conductive devices thereon are non-transparent regions and transparent substrate areas having no conductive devices thereon are transparent regions. Using the substrate as a mask, a contact exposure of the photoresist material is conducted to form a patterned photoresist layer by shining light through the transparent substrate regions.

### BACKGROUND OF THE INVENTION

1. Field of Invention

The present invention relates to a semiconductor process. More particularly, the present invention relates to a self-aligned photolithographic process for forming silicon-on-insulator devices.

2. Description of Related Art

Following the reduction in line width of semiconductor devices, complicated design rules are required. In photolithographic process, line width reduction not only leads to an increase in device density and pattern complexity on silicon wafers, but also leads to a reduction in the separation between neighboring lines. Consequently, more stringent alignment criteria must be set aside for fabricating an integrated circuit.

In a conventional photolithographic process, photoresist material is deposited over an etching layer over a wafer. A photo-exposure of the photoresist layer is carried out by projecting light from a light source through a photomask. Pattern on the photomask is transferred to the wafer by a step-and-repeat process or a step-and-scan method. The pattern thus transferred to the wafer has an optimal resolution. However, the photolithographic process involves relatively complicated steps. Moreover, the resulting pattern is limited by the alignment accuracy of the photomask, the magnification, the tolerance, the alignment accuracy of the stepper/scanner and the other mechanical synchronization problems. Hence, process window of the fabrication process is tight rendering alignment difficult.

### SUMMARY OF THE INVENTION

Accordingly, one object of the present invention is to provide a self-aligned photolithographic process for forming silicon-on-insulator devices. By performing a photo-exposure of the regions of a transparent insulation substrate having no devices thereon, the number of photomasks required in the fabrication process is reduced.

A second object of this invention is to provide a self-aligned photolithographic process for forming silicon-on-insulator devices such that production cost is reduced and degree of difficulty in production is minimized.

A third object of this invention is to provide a self-aligned photolithographic process for forming silicon-on-insulator devices that effects a self-aligned photo-exposure process so that misalignment is prevented.

A fourth object of this invention is to provide a self-aligned photolithographic process for forming silicon-on-insulator devices capable of using contact exposure to increase overall resolution of exposed pattern.

To achieve these and other advantages and in accordance with the purpose of the invention, as embodied and broadly described herein, the invention provides a self-aligned photolithographic process for forming silicon-on-insulator devices. A substrate made from a transparent insulating material is provided. A conductive device made from a non-transparent material is formed over the substrate. A transparent material layer is formed over the substrate. A photoresist layer is formed over the material layer. Using the substrate as a mask for a self-aligned photolithographic process, a contact exposure process is conducted. In the contact exposure process, the area of the substrate having the conductive devices thereon is used as a non-transparent region and the area of the substrate having no conductive devices thereon is used as a transparent region. During contact exposure, light from a light source underneath the substrate passes through the transparent regions of the substrate and patterns the photoresist layer above.

One major aspect of this invention is the selection of a transparent material to form the substrate of silicon-on-insulator devices. Hence, a photolithographic exposure can be conducted by shining a light beam through the transparent region in-between devices on the substrate.

Because substrate areas having conductive devices thereon are non-transparent regions and substrate areas having no conductive devices thereon are transparent regions, the substrate can serve as a mask in a self-aligned photolithographic process. Hence, no additional mask is required.

Since a contact exposure of the transparent substrate regions besides the device regions can be conducted, ultimate resolution of the exposure pattern is much higher than the pattern produced by a conventional projection exposure method.

Furthermore, since the transparent substrate regions having no devices thereon are used directly in contact exposure, the exposure is a self-aligned process. Consequently, the pattern can be accurately transferred to the substrate on one side of the devices. Unlike a conventional process, alignment errors resulting from projection through a mask are eliminated.

In addition, because the photolithographic process of this invention requires no photomask or other exposure equipment necessary for conducting a conventional projection exposure, production cost, production time and the level of difficulty in production is greatly reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1E are schematic cross-sectional views showing the progression of steps for forming a contact using a self-aligned photolithographic process for forming a silicon-on-insulator device according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

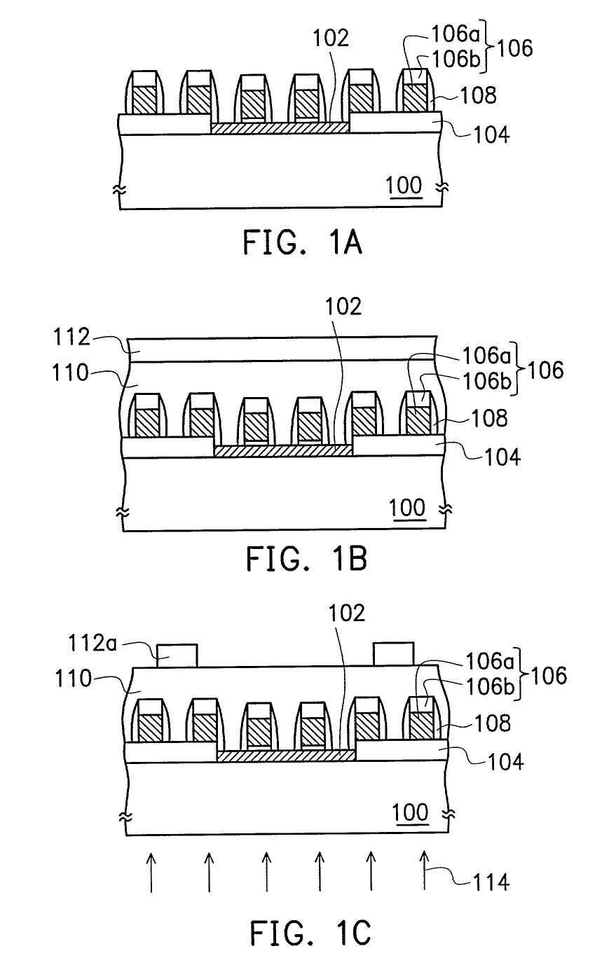

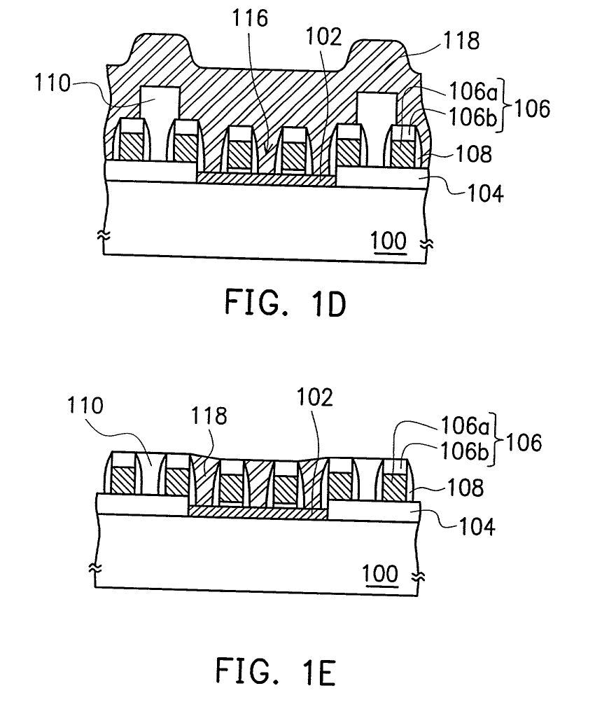

FIGS. 1A through 1E are schematic cross-sectional views showing the progression of steps for forming a contact using a self-aligned photolithographic process for forming a silicon-on-insulator device according to one preferred embodiment of this invention. As shown in FIG. 1A, a substrate 100 is provided. The substrate 100 can be made from a transparent insulating material such as silicon oxide. An active device layer 102 for forming the silicon-on-insulator devices is formed over the substrate 100. The active device layer 102 can be made from a material such as silicon. Isolation layers 104 are formed over the silicon oxide substrate 100 on each side of the active device layer 102 so that the active device region 102 is isolated from other device regions. The isolation layers 104 are also fabricated from a transparent material such as silicon oxide.

Word lines 106 are formed over the substrate 100 covering a portion of the active device region 102 and a portion of the isolation layer 104. Each word line 106 includes a conductive layer 106a and a cap layer 106b. The conductive layer 106a can be, for example, a polysilicon, a polycide or a metallic layer. The cap layer 106 can be, for example, a silicon nitride layer. A spacer 108 is formed on the sidewalls of each word line 106. The spacers 108 can be silicon nitride layers, for example.

Here, the active device region 102 and the word lines 106 can be regarded as conductive devices on the substrate 100. Furthermore, the active device region 102 and the word lines 106 are both made from non-transparent material. Hence, the conductive devices (active device region 102 and the word lines 106) can be regarded as nontransparent regions in the substrate mask for a subsequent photo-exposure.

As shown in FIG. 1B, a material layer 110 is formed over the substrate 100. The material layer 110 is made from a transparent insulating material such as silicon oxide. The material layer is formed, for example, by chemical vapor deposition. A photoresist layer 112 is formed over the material layer 110. The photoresist layer can be a positive or a negative photoresist layer depending on the actual processing application. A negative photoresist layer formed by spin coating is used as an illustration in this invention.

As shown in FIG. 1C, using the substrate 100 as a mask, a self-aligned photolithographic process 114 of the photoresist layer 112 is conducted to form a patterned photoresist layer 112a. The self-aligned photolithographic process 114 is conducted from the backside of the substrate 100 through the regions that have no conductive devices thereon. No other photomask except the substrate is used in the photolithographic process. The areas in the substrate 100 having conductive devices thereon (the active device region 102 and the word lines 106) are used as non-transparent regions. Conversely, the areas in the substrate 100 having no conductive devices are used as transparent regions. The photolithographic process is a direct contact exposure. Light from a light source shines through the transparent regions between the conductive devices to the photoresist layer 112. The exposed portion of the photoresist layer 112 reacts photo-chemically. Energy level of the exposure is between 20 millijoules/cm² to 40 millijoules/cm². Thereafter, the exposed photoresist layer 112 is chemically developed to form a photoresist layer 112a.

Since the substrate 100, the isolation layers 104 and the material layer 110 are all made from a transparent material, a photolithographic process from the backside of the substrate 100 is possible. In addition, the conductive devices (the active device region 102 and the word lines 106) on the substrate 100 are made from non-transparent material, thereby forming non-transparent regions. Hence, the entire substrate 100 can be regarded as a patterned photomask if photo-exposure is conducted by shining from the backside of the substrate 100. Ultimately, no additional photomask is required. Because exposure using the substrate 100 as a mask is actually a contact exposure, resolution of the ultimately formed pattern is considerably higher than the pattern provided by a conventional projection exposure. Furthermore, since the substrate 100 itself is used as a mask, the photo-exposure can be regarded as a self-aligned process. The pattern is transferred to the regions besides the devices on the substrate 100 without any alignment errors. Without the need to fabricate photomask and perform projection exposure, production cost and the level of difficulty in production is minimized.

As shown in FIG. 1D, the material layer 110 outside the photoresist layer 112a is removed to form an opening 116 by performing an anisotropic etching using the photoresist layer 112a as a mask. The bottom of the opening 116 exposes the active device region 102. Conductive material is deposited over the substrate 100, completely filling the opening 116 to form a conductive layer 118. The conductive layer can be a polysilicon layer formed, for example, by chemical vapor deposition.

As shown in FIG. 1E, chemical mechanical polishing or etching is conducted to remove a portion of the conductive layer 118 and to remove a portion of the insulation layer 110. The cap layers 106b over the word lines 106 are used as a polishing stop layer or an etching stop layer. The conductive layer 118 inside the opening 116 serves as a landing pad for a subsequently formed contact so that the aspect ratio of the contact opening is reduced.

In this invention, the self-aligned photolithographic process for forming siliconon-insulator devices can be applied to fabricate the landing pad of a contact. However, this invention is not limited to the fabrication of the contacts of a silicon-on-insulation device. The photolithographic process can be applied to any substrate fabricated from transparent insulating material. Using the substrate as a mask that includes non-transparent regions of conductive devices and transparent regions of transparent substrate material, the self-aligned photolithographic process of this invention is carried out.

In summary, one major aspect of this invention is the selection of a transparent material to form the substrate of silicon-on-insulator devices. Hence, a photolithographic exposure can be conducted by shining a light beam through the transparent region in-between devices on the substrate.

Because substrate areas having conductive devices such as an active device layer and word lines thereon are non-transparent regions and substrate areas having no conductive devices thereon are transparent regions, the substrate can serve as a mask in a self-aligned photolithographic process. Hence, no additional mask is required.

Since a contact exposure of the transparent substrate regions besides the device regions can be conducted, ultimate resolution of the exposure pattern is much higher than the pattern produced by a conventional projection exposure method.

Furthermore, since the transparent substrate regions having no devices thereon are used directly in contact exposure, the exposure is a self-aligned process. Consequently, the pattern can be accurately transferred to the substrate on one side of the devices. Unlike a conventional process, alignment errors resulting from projection through a mask is eliminated.

In addition, because the photolithographic process of this invention requires no photomask or other exposure equipment necessary for conducting a conventional projection exposure, production cost, production time and the level of difficulty in production is greatly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A self-aligned photolithographic process for forming a silicon-on-insulator device, comprising:
providing a substrate having a plurality of conductive devices formed thereon, wherein the substrate is made from a transparent material and the conductive devices are made from a non-transparent material;
forming a material layer over the substrate, wherein the material layer is made from a transparent material;
forming a photoresist layer over the material layer;
conducting a contact exposure of the photoresist layer by shining a beam of light from a light source through the transparent regions of the substrate while using the substrate itself as a mask, wherein substrate areas having conductive devices thereon are non-transparent regions and substrate areas having no conductive devices thereon are transparent regions; and
performing a post-exposure chemical development to form a pattern on the photoresist layer.

2. The process of claim 1, wherein material forming the substrate includes silicon oxide.

3. The process of claim 1, wherein material forming the conductive devices is selected from a group consisting of silicon, metal silicide and metal.

4. The process of claim 1, wherein material forming the material layer includes silicon oxide.

5. The process of claim 1, wherein the photoresist layer is a positive photoresist layer or a negative photoresist layer.

6. The process of claim 5, wherein forming the photoresist layer includes spin coating.

7. The process of claim 1, wherein an energy level used in the contact exposure is about 20 millijoules/cm² to 40 millijoules/cm².

8. A self-aligned photolithographic process for forming a silicon-on-insulator device, comprising:
providing a substrate, wherein the substrate is made from a transparent material;
forming an active device layer over the substrate, wherein the active device layer is made from a non-transparent material;
forming an isolation layer over the substrate on each side of the active device layer, wherein the isolation layer is made from a transparent material;
forming a plurality of word lines over the substrate, wherein the word lines are formed over a portion of the active device layer and a portion of the isolation layers, and each word line further includes a first conductive layer, a cap layer and a spacer on sidewalls of the first conductive layer and the cap layer;
forming an insulation layer over the substrate, wherein the insulation layer is made from a transparent material;
forming a photoresist layer over the insulation layer, conducting a contact exposure of the photoresist layer by shining a beam of light from a light source through the transparent regions of the substrate, wherein the active device layer and the word lines over the substrate are non-transparent regions and the isolation layers having no word lines thereon are transparent regions;
performing a post-exposure photoresist development to form a patterned photoresist layer, wherein the patterned photoresist layer covers the transparent region;
removing the insulation layer outside the photoresist covered region using the patterned photoresist layer as a mask to form a plurality of openings in the active device region;
removing the patterned photoresist layer;
forming a second conductive layer over the substrate such that the second conductive layer also completely fills the openings; and
removing a portion of the second conductive layer and the insulation layer to expose the cap layer so that a plurality of conductors is formed inside the openings.

9. The process of claim 8, wherein material forming the substrate includes silicon oxide.

10. The process of claim 8, wherein material forming the active device layer includes silicon.

11. The process of claim 8, wherein material forming the isolation layers includes silicon oxide.

12. The process of claim 8, wherein material forming the insulation layer includes silicon oxide.

13. The process of claim 8, wherein material forming the photoresist layer includes negative photoresist.

14. The process of claim 13, wherein forming the photoresist layer includes spin coating.

15. The process of claim 8, wherein an energy level for conducting photo-exposure is about 20 millijoules/cm² to 40 millijoules/cm².

16. The process of claim 8, wherein removing the insulation layer outside the patterned photoresist layer includes performing an anisotropic etching.

17. The process of claim 8, wherein removing the portion of the second conductive layer and the portion of the insulation layer includes chemical-mechanical polishing.

18. The process of claim 8, wherein removing the portion of the second conductive layer and the portion of the insulation layer includes back etching.
